(19) United States
(12) Patent Application Publication
(10) Pub. No.: US 2006/0232165 A1
(43) Pub. Date: Oct. 19, 2006

(54) Ultrasonic transmitter-receiver

(76) Inventors: Shinji Amaike, Kyoto-fu (JP); Masanaga Nishikawa, Kyoto-fu (JP)

Correspondence Address: MURATA MANUFACTURING COMPANY, LTD.;C/O KEATING & BENNETT, LLP, 8180 GREENSBORO DRIVE, SUITE 850, MCLEAN, VA, 22102, US

(21) Appl. No.: 10/564,672

(22) PCT Filed: Jun. 7, 2004
(86) PCT No.: PCT/JP04/07940

§ 371 Date: May 10, 2006

(30) Foreign Application Priority Data
Jul. 6, 2003 (JP) 2003-198039

(51) Int. Cl. H01L 41/08

(52) U.S. Cl. 310/322

(57) ABSTRACT

An ultrasonic transmitting and receiving apparatus includes a casing, a vibration isolating member, and a piezoelectric element. The casing has a bottom, an inner peripheral wall, and an outer peripheral wall, and these components are integral and define a monolithic structure. The inner peripheral wall and the bottom define a first recess. The outer peripheral wall, the inner peripheral wall, and the bottom define a second recess. The second recess is filled with the vibration isolating member. The piezoelectric element is fixed on the bottom facing the first recess in the casing.

### BACKGROUND OF THE INVENTION

1. Field of the Invention

The present invention relates to an ultrasonic transmitting and receiving apparatus used in an obstacle sensor, such as rear sonar and corner sonar in a vehicle.

2. Description of the Related Art

Ultrasonic transmitting and receiving apparatuses perform sensing by using ultrasonics. An ultrasonic transmitting and receiving apparatus intermittently transmits an ultrasonic pulse from a piezoelectric resonator and receives a wave reflected back from an object. The distance to the object is determined on the basis of the signal in wave transmission and reception. The piezoelectric resonator is secured to the inside of a bottom of a casing, with the bottom of the casing serving as a vibrating surface. However, unwanted external vibrations are often conveyed from a side wall of the casing to the bottom and the piezoelectric resonator mounted to the inner surface of the bottom. Furthermore, since vibrations occurring in the vibrating surface of the casing are also conveyed to the side wall of the casing, the vibrations can affect characteristics of the ultrasonic transmitting and receiving apparatus, such as reverberation characteristics, depending on how the side wall of the casing is arranged and held.

In order to address such a problem, an ultrasonic transmitting and receiving apparatus is described in Japanese Unexamined Patent Application Publication No. 2001-016694, which is described below. This ultrasonic transmitting and receiving apparatus includes a tubular casing in which an ultrasonic resonator is fixed to a bottom which defines a diaphragm. An external frame for supporting the tubular casing is disposed outside the tubular casing. An intervening member for absorbing the energy of vibrations is disposed between the external frame and the frame of the tubular casing.

However, the ultrasonic transmitting and receiving apparatus described in Japanese Unexamined Patent Application Publication No. 2001-016694 has the following problems.

The ultrasonic transmitting and receiving apparatus includes the intervening member disposed outside the tubular casing containing the ultrasonic resonator in order to absorb the energy of vibrations. In the case of the ultrasonic transmitting and receiving apparatus mounted on a vehicle or the like, the intervening member cannot be directly attached to the vehicle or the like, and therefore, the external frame functioning as a support member is disposed outside the intervening member. As a result, since the intervening member and the external frame are necessary in addition to the tubular casing, the number of components is increased, thus resulting in an increased manufacturing cost. Moreover, when the ultrasonic transmitting and receiving apparatus is mounted on a vehicle or the like, a problem arises in which a layered structure of the tubular casing, the intervening member, and the external frame degrades the appearance of the vehicle or the like.

Furthermore, since a side of the bottom to which the ultrasonic resonator is mounted is arranged so as to be exposed to the outside in order to perform wave transmission and reception, the intervening member disposed between the tubular casing and the external frame is exposed to the outside. This results in unreliability, such as poor durability.

### SUMMARY OF THE INVENTION

In order to overcome the problems described above, preferred embodiments of the present invention provide an ultrasonic transmitting and receiving apparatus that prevents and minimizes degraded characteristics caused by external vibrations, has a reduced number of components and thus can be manufactured at low cost, has an enhanced appearance when used on a vehicle, and has an increased reliability, such as excellent durability.

An ultrasonic transmitting and receiving apparatus according to a preferred embodiment of the present invention has a structure in which a piezoelectric element is mounted to a bottom of a casing. The apparatus includes a casing including a bottom, an outer peripheral wall, and an inner peripheral wall. The outer peripheral wall is disposed on an inner surface of the bottom and integrally extends away from the bottom. The inner peripheral wall is disposed on the inner surface of the bottom, integrally extends away from the bottom, and is arranged inside the outer peripheral wall. The inner peripheral wall and the bottom define a first recess. The outer peripheral wall, the inner peripheral wall, and the bottom define a second recess. The apparatus further includes a piezoelectric element mounted to a portion of the bottom, the portion being exposed to the first recess, and a vibration isolating member with which the second recess is filled.

In the ultrasonic transmitting and receiving apparatus according to a preferred embodiment of the present invention, a cross section of the first recess has an anisotropic shape, the cross section being surrounded by the inner peripheral wall and defined along a direction parallel to the bottom. Preferably, the anisotropic shape may be substantially elliptical.

In the ultrasonic transmitting and receiving apparatus according to another preferred embodiment of the present invention, the bottom includes a thick portion and a thin portion in the portion exposed to the first recess, the thick portion being thicker than the thin portion and the thin portion being thinner than the thick portion, and the piezoelectric element is mounted to the thick portion.

In the ultrasonic transmitting and receiving apparatus according to still another preferred embodiment of the present invention, a cross section of a portion surrounded by an inside surface of the outer peripheral wall is circular, the cross section being defined along a direction parallel to the bottom.

In the ultrasonic transmitting and receiving apparatus according to a further preferred embodiment of the present invention, the thickness of the inner peripheral wall is equal to or smaller than the thickness of the outer peripheral wall.

In the ultrasonic transmitting and receiving apparatus according to the preferred embodiment described above, the casing is formed as one piece such that the bottom is integral with the inner peripheral wall and the outer peripheral wall. Therefore, a reduced number of components can minimize an increase in the manufacturing cost. Since the outermost portion of the ultrasonic transmitting and receiving apparatus is the casing, the ultrasonic transmitting and receiving apparatus can be directly mounted on a vehicle. Additionally, since the vibration isolating member is not exposed to a side adjacent to a vibrating surface, that is, the outside, an ultrasonic transmitting and receiving apparatus that has increased reliability and enhanced appearance can be provided.

Other features, elements, steps, characteristics and advantages of the present invention will become more apparent from the following detailed description of preferred embodiments of the present invention with reference to the attached drawings.

### BRIEF DESCRIPTION OF THE DRAWINGS

FIG. 1 is a schematic plan view of an ultrasonic transmitting and receiving apparatus according to a first preferred embodiment of the present invention.

FIG. 2 is a schematic cross-sectional view of the ultrasonic transmitting and receiving apparatus according to the first preferred embodiment of the present invention.

FIG. 3 is a schematic plan view of an ultrasonic transmitting and receiving apparatus according to a second preferred embodiment of the present invention.

FIG. 4 is a schematic cross-sectional view of the ultrasonic transmitting and receiving apparatus according to the second preferred embodiment of the present invention.

FIG. 5 is a schematic cross-sectional view of an ultrasonic transmitting and receiving apparatus according to a third preferred embodiment of the present invention.

FIG. 6 is a schematic plan view of an ultrasonic transmitting and receiving apparatus according to a fourth preferred embodiment of the present invention.

### DETAILED DESCRIPTION OF PREFERRED EMBODIMENTS

Preferred embodiments of the present invention are described below with reference to the accompanying drawings.

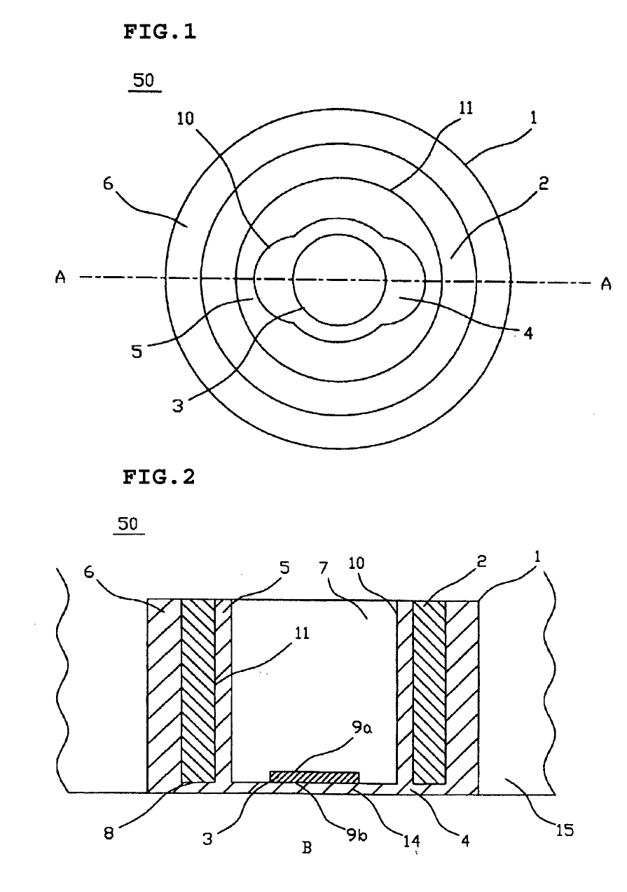

FIG. 1 is a schematic plan view of an ultrasonic transmitting and receiving apparatus according to a first preferred embodiment of the present invention. FIG. 2 is a sectional view taken along the line A-A of FIG. 1.

In FIGS. 1 and 2, an ultrasonic transmitting and receiving apparatus 50 includes a casing 1, a vibration isolating member 2, and a piezoelectric element 3.

The casing 1 includes a bottom 4, an inner peripheral wall 5, and an outer peripheral wall 6. The bottom 4 is integral with the inner peripheral wall 5 and the outer peripheral wall 6. In other words, the casing 1 is formed as one piece. The inner peripheral wall 5 is disposed on an inner surface of the bottom 4 and integrally extends away from the bottom 4. The outer peripheral wall 6 is also disposed on the inner surface of the bottom 4 and integrally extends away from the bottom 4. The inner peripheral wall 5 is arranged inside the outer peripheral wall 6.

The casing 1 is preferably made of, though not limited to, a metallic material. Preferable examples of the metallic material include aluminum, which is light in weight, easy to machine, and is corrosion-resistant, an aluminum alloy, and the like. In the casing 1, the bottom 4 and the inner peripheral wall 5 define a first recess 7. Inside the first recess 7, the piezoelectric element 3 is fixed on a top surface of the bottom 4. A portion of the bottom 4 that faces the first recess 7 defines a vibrating surface 14.

The piezoelectric element 3 has a structure in which first and second element electrodes 9a and 9b are arranged on the opposite principal surfaces of a piezoelectric substrate. The second element electrode 9b is bonded preferably with a conductive adhesive to a central portion of the inner surface of the bottom 4 facing the first recess 7. The first element electrode 9a of the piezoelectric element 3 accommodated in the casing 1 is attached to a lead (not illustrated) and the like for electrical connection.

In the ultrasonic transmitting and receiving apparatus 50, when an alternating voltage is applied to the piezoelectric element 3, the vibrating surface 14 is vibrated, a sound wave is generated, and the sound wave is emitted to an exterior B which is adjacent to an outer surface of the bottom 4. In contrast, when a reflected wave from an object is received, the vibrating surface 14 is vibrated, distortion generated by this vibration is converted into an electrical signal by the piezoelectric element 3, and detection of the object is thus performed.

The bottom 4, the inner peripheral wall 5, and the outer peripheral wall 6 define a second recess 8. The second recess 8 is filled with the vibration isolating member 2. The vibration isolating member 2 is preferably formed of an elastic material, such as an elastic adhesive, or the like, made of silicon rubber, polyurethane rubber, or any other suitable material. The vibration isolating member 2 functions to reduce reverberation vibrations in the vibrating surface 14 and shorten the reverberation time in reception. As a result, satisfactory reverberation characteristics are achieved. Additionally, since the vibration isolating member 2 is arranged so as not to be in contact with the piezoelectric element 3, the vibration isolating member 2 does not affect the excitation of the piezoelectric element 3. Therefore, reverberation vibrations can be reduced without having to change the resonance frequency or the sensitivity of the ultrasonic transmitting and receiving apparatus 50. Moreover, unwanted external vibrations conveyed to the vibrating surface 14 and the piezoelectric element 3 can be reduced.

Furthermore, the structure of the casing 1 described above allows the ultrasonic transmitting and receiving apparatus 50 to be directly mounted on a vehicle 15. Since the outer surface of the bottom 4 serves as a portion exposed to the exterior B when the ultrasonic transmitting and receiving apparatus 50 is mounted on the vehicle 15, the vibration isolating member 2 is not exposed to the exterior B. As a result, the durability is also increased.

A cross section of an internal portion 10 of the inner peripheral wall 5, the cross section being defined along a direction parallel to the bottom 4, has a substantially elliptical shape, in which axes perpendicular to each other have different dimensions. This structure allows directional characteristics to have anisotropy. The cross section of the internal portion 10 is not limited to an elliptical shape. If the cross section, which is defined along a direction parallel to the bottom 4, of the internal portion 10 of the inner peripheral wall 5 is not circular and has an anisotropic shape, directional characteristics are allowed to have anisotropy, as in the above-described case. As a result, the cross section is not limited to the substantially elliptical shape shown in FIG. 1, and may have various anisotropic shapes. In FIG. 1 and FIG. 2, a cross section of an external portion 11 of the inner peripheral wall 5 is circular.

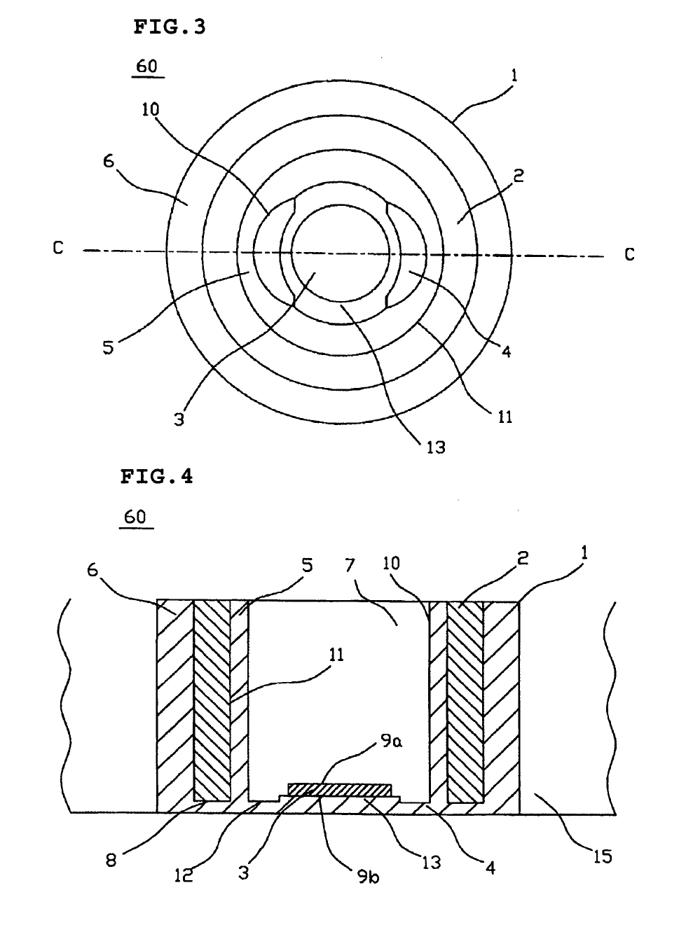

FIG. 3 is a schematic plan view of an ultrasonic transmitting and receiving apparatus according to a second preferred embodiment of the present invention. FIG. 4 is a schematic cross-sectional view taken along the line C-C of FIG. 3. In an ultrasonic transmitting and receiving apparatus 60 shown in FIGS. 3 and 4, the same reference numerals are used as in FIGS. 1 and 2 for similar components. The explanation of the similar components to those in FIGS. 1 and 2 is omitted.

In the ultrasonic transmitting and receiving apparatus 60 in FIGS. 3 and 4, the bottom 4 includes a thin portion 12 and a thick portion 13 in a portion exposed to the first recess 7. The piezoelectric element 3 is fixed on the thick portion 13.

In the first recess 7, the thin portion 12 is arranged such that the thin portion 12 of the bottom 4 has a larger area in a direction of a longer axis of the substantially elliptical shape, which is similar to the shape described above in the first recess 7. Therefore, the ultrasonic transmitting and receiving apparatus 60 can have a narrow directivity in the direction of the longer axis, and the ultrasonic transmitting and receiving apparatus 60 with a directivity having high anisotropy can be achieved. Since the piezoelectric element 3 is mounted to the thick portion 13, the impact resistance is also increased.

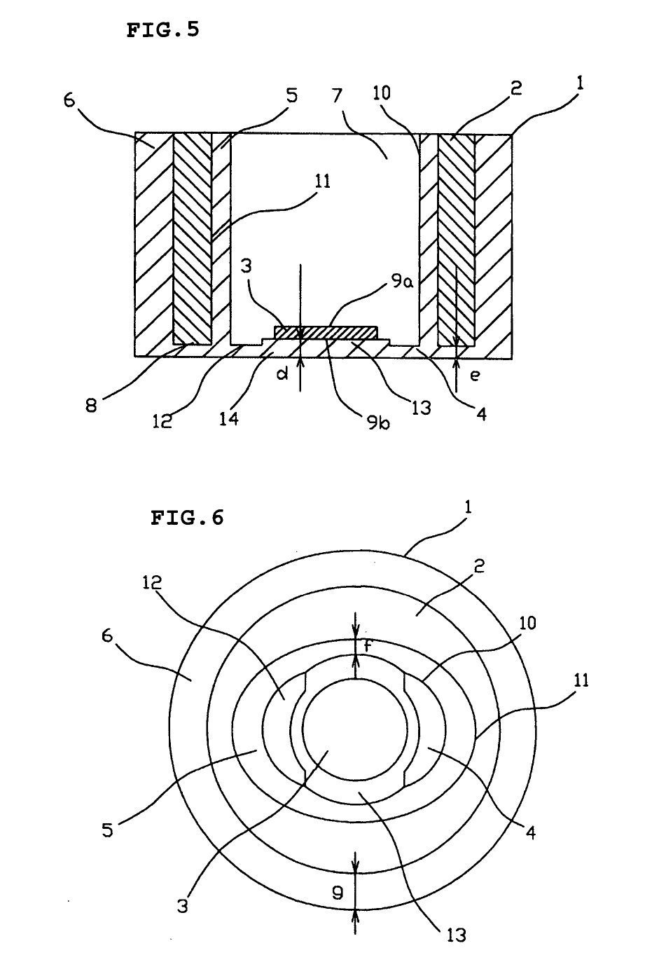

FIG. 5 is a schematic cross-sectional view of an ultrasonic transmitting and receiving apparatus according to a third preferred embodiment of the present invention.

As shown in FIG. 5, the thickness d of the thick portion 13 of the bottom 4 facing the first recess 7 is equal to or larger than the thickness e of the bottom 4 facing the second recess 8. This structure can further reduce conveyance of vibrations of the vibrating surface 14 to the outer peripheral wall 6 of the casing 1. In FIG. 5, the same reference numerals are used as in FIG. 4 for similar components. The explanation of the similar components is omitted.

FIG. 6 is a schematic plan view of an ultrasonic transmitting and receiving apparatus according to a fourth preferred embodiment of the present invention.

As shown in FIG. 6, a cross section of the internal portion 10 of the inner peripheral wall 5 and that of an external portion 11, the cross sections being parallel to the bottom 4, are elliptically shaped, and both the elliptical shapes have the same center. The thickness f of the inner peripheral wall 5 of the casing 1 is equal to or smaller than the thickness g of the outer peripheral wall 6. This structure can further reduce conveyance of vibrations of the vibrating surface 14 included in the bottom 4 to the outer peripheral wall 6 of the casing 1. In FIG. 6, the same reference numerals are used as in FIG. 3 for similar components. The explanation of the similar components is omitted.

While preferred embodiments of the present invention have been described above, it is to be understood that variations and modifications will be apparent to those skilled in the art without departing the scope and spirit of the present invention. The scope of the present invention, therefore, is to be determined solely by the following claims.

1-6. (canceled)

7. An ultrasonic transmitting and receiving apparatus comprising:
a casing including a bottom, an outer peripheral wall, and an inner peripheral wall, the outer peripheral wall being integral with the bottom and extending from an inner surface of the bottom, the inner peripheral wall being integral with the bottom and extending from the inner surface of the bottom, a space surrounded by the inner peripheral wall and the bottom defining a first recess, and a space surrounded by the inner peripheral wall, the outer peripheral wall, and the bottom defining a second recess;
a piezoelectric element mounted to the bottom and facing the first recess; and
a vibration isolating member filling the second recess.

8. The ultrasonic transmitting and receiving apparatus according to claim 7, wherein a cross section of the first recess has an anisotropic shape, the cross section being taken along a direction parallel to the bottom and being defined by an inside surface of the inner peripheral wall.

9. The ultrasonic transmitting and receiving apparatus according to claim 8, wherein the anisotropic shape is substantially elliptical.

10. The ultrasonic transmitting and receiving apparatus according to claim 8, wherein a cross section of an inside surface of the outer peripheral wall is circular, the cross section being taken along a direction parallel to the bottom.

11. The ultrasonic transmitting and receiving apparatus according to claim 9, wherein the bottom includes a thick portion and a thin portion, the piezoelectric element is mounted to the thick portion, and the thin portion extends along a major axis of the elliptical shape.

12. The ultrasonic transmitting and receiving apparatus according to claim 7, wherein a cross section of an inside surface of the outer peripheral wall is circular, the cross section taken along a direction parallel to the bottom.

13. The ultrasonic transmitting and receiving apparatus according to claim 7, wherein the bottom includes a thick portion and a thin portion, and the piezoelectric element is mounted to the thick portion.

14. The ultrasonic transmitting and receiving apparatus according to claim 13, wherein at least a portion of the thin portion faces the first recess.

15. The ultrasonic transmitting and receiving apparatus according to claim 13, wherein at least a portion of the thin portion faces the second recess.

16. The ultrasonic transmitting and receiving apparatus according to claim 7, wherein a thickness of the inner peripheral wall is equal to or smaller than a thickness of the outer peripheral wall.

17. The ultrasonic transmitting and receiving apparatus according to claim 7, wherein a cross section of the inner peripheral wall has an anisotropic shape, the cross section being taken along a direction parallel to the bottom and being defined by an outside surface of the inner peripheral wall.
